(19) United States
(12) Patent Application Publication
(10) Pub. No.: US 2025/0218718 A1
(43) Pub. Date: Jul. 3, 2025

(54) CONTAMINATION PREVENTION DEVICE FOR EXTREME ULTRA-VIOLET (EUV) RETICLE AND EUV EXPOSURE APPARATUS INCLUDING THE SAME

(71) Applicant: SAMSUNG ELECTRONICS CO., LTD., Suwon-si (KR)

(72) Inventors: Hoonseop KIM, Suwon-si (KR); Sangki NAM, Suwon-si (KR); Sungho JANG, Suwon-si (KR); Jehoi MUN, Suwon-si (KR); Nali YOO, Suwon-si (KR); Changwook LEE, Suwon-si (KR)

(73) Assignee: SAMSUNG ELECTRONICS CO., LTD., Suwon-si (KR)

(21) Appl. No.: 18/753,601

(22) Filed: Jun. 25, 2024

(30) Foreign Application Priority Data
Dec. 27, 2023 (KR) 10-2023-0193180

(51) Int. Cl. H01J 37/06; G03F 7/00

(52) U.S. Cl. CPC H01J 37/06; G03F 7/70033; G03F 7/7085; G03F 7/70916; H01J 2237/0044; H01J 2237/022

(57) ABSTRACT

Provided is a contamination prevention device configured to prevent contamination of extreme ultra-violet (EUV) reticle, including at least one electron source including a first electron source on a first side of the EUV reticle outside a space between the EUV reticle and a slit-plate, wherein, during an EUV exposure process, the at least one electron source is further configured to emit the electrons into the space to neutralize the EUV reticle.

### CROSS-REFERENCE TO RELATED APPLICATION

This application claims priority to Korean Patent Application No. 10-2023-0193180, filed on Dec. 27, 2023, in the Korean Intellectual Property Office, the disclosure of which is incorporated by reference herein in its entirety.

### BACKGROUND

Embodiments of the present disclosure relate to an extreme ultra-violet (EUV) exposure apparatus, and more particularly, to a contamination prevention device for preventing contamination for an EUV reticle and an EUV exposure apparatus including the contamination prevention device.

Recently, as the line width of semiconductor circuits has become increasingly smaller, light sources with shorter wavelengths have been required. For example, EUV light is used as an exposure source. Due to the absorption characteristics of EUV light, a reflective EUV reticle is generally used in an EUV exposure process. Additionally, illumination optics for transmitting EUV light to an EUV reticle and projection optics for projecting EUV light reflected from the EUV reticle to an exposure target may include a plurality of mirrors. As the difficulty of the exposure process increases, small errors occurring in the EUV reticle may cause serious errors in pattern formation on a wafer.

### SUMMARY

One or more embodiments provide a contamination prevention device for extreme ultra-violet (EUV) reticle that may more effectively prevent contamination of the EUV reticle, and an EUV exposure apparatus including the contamination prevention device.

In addition, embodiments are not limited to the matter mentioned above, and other matters may be clearly understood by those skilled in the art from the description below.

According to an aspect of one or more embodiments, there is provided a contamination prevention device configured to prevent contamination of extreme ultra-violet (EUV) reticle, including at least one electron source including a first electron source on a first side of the EUV reticle outside a space between the EUV reticle and a slit-plate, wherein, during an EUV exposure process, the at least one electron source is configured to emit the electrons into the space to neutralize the EUV reticle.

According to another aspect of one or more embodiments, there is provided a contamination prevention device configured to prevent contamination of extreme ultra-violet (EUV) reticle, including at least one electron source including a first electron source on a first side of the EUV reticle outside a space between the EUV reticle and the slit-plate, a first sensor in the space adjacent to a slit position of the slit-plate, the first sensor being configured to detect plasma in an EUV exposure process, and a second sensor in the space adjacent to the slit position of the slit-plate, the second sensor being configured to measure a surface charge of the EUV reticle, wherein, during an EUV exposure process, the at least one electron source is configured to emit the electrons into the space to neutralize the EUV reticle.

According to still another aspect of one or more embodiments, there is provided an extreme ultra-violet (EUV) exposure apparatus including an EUV source configured to generate and emit EUV, a reticle stage configured to support an EUV reticle, a substrate stage configured to support a substrate subject to EUV exposure, a first optical system configured to transmit EUV from the EUV source to the EUV reticle, a second optical system configured to transmit EUV reflected from the EUV reticle to the substrate, and a contamination prevention device configured to prevent contamination of the EUV reticle from particles, wherein the contamination prevention device for the EUV reticle includes at least one electron source including a first electron source on a first side of the EUV reticle external to a space between the EUV reticle and a slit-plate, and wherein, during an EUV exposure process, the at least one electron source is configured to emit the electrons into the space to neutralize the EUV reticle.

### BRIEF DESCRIPTION OF DRAWINGS

Embodiments will be more clearly understood from the following detailed description taken in conjunction with the accompanying drawings in which:

FIG. 1 is a conceptual diagram schematically illustrating a contamination prevention device for an ultra-violet (EUV) reticle, according to one or more embodiments;

FIGS. 2A and 2B are conceptual diagrams illustrating prevention of contamination of a reticle in a deep ultra-violet (DUV) exposure process and an EUV exposure process;

FIGS. 3A and 3B are conceptual diagrams illustrating an operation of an EUV reticle being charged in the EUV exposure process;

FIGS. 4A and 4B are graphs illustrating a charge amount of particles over time and forces acting on particles depending on size during the exposure process;

FIGS. 5A, 5B, and 5C are conceptual diagrams illustrating a process of preventing contamination of the EUV reticle through the contamination prevention device for EUV reticle shown in FIG. 1;

FIGS. 6A, 6B, 6C, 6D, 6E, and 6F are conceptual diagrams illustrating in more detail a process of neutralizing the EUV reticle through electron emission from an electron source shown in FIG. 5C;

FIGS. 7A, 7B, and 7C are conceptual diagrams illustrating a speed at which particles move by electric force while the EUV reticle is charged with positive charges;

FIGS. 8A, 8B, and 8C are conceptual diagrams illustrating a direction and speed at which particles move while the EUV reticle is neutralized; and

FIG. 9 is a conceptual diagram schematically illustrating an EUV exposure apparatus including a device for preventing contamination of an EUV reticle according to one or more embodiments.

### DETAILED DESCRIPTION

Hereinafter, embodiments are described in detail with reference to the attached drawings. The same reference numerals are used for the same components in the drawings, and the descriptions already given for the components are omitted.

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

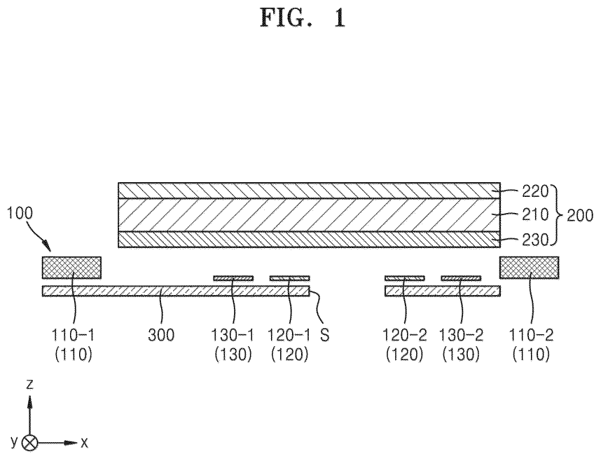

FIG. 1 is a conceptual diagram schematically illustrating a contamination prevention device for an extreme ultra-violet (EUV) reticle, according to one or more embodiments.

Referring to FIG. 1, a contamination prevention device 100 for an EUV reticle according to one or more embodiments may include an electron source 110, a plasma sensor 120, and a surface charge sensor 130.

The electron source 110 may generate and emit electrons. For example, the electron source 110 may include an electron gun. However, the electron source 110 is not limited to the electron gun. For example, the electron source 110 may include a thermionic source, a hollow cathode emitter, etc. However, embodiments are not limited thereto, and all types of devices that emit electrons may be collectively referred to as electron guns.

The electron source 110 may be placed adjacent to one side of an EUV reticle 200 outside the space between the EUV reticle 200 and a slit-plate 300. As shown in FIG. 1, two electron sources 110 may be disposed on both sides of the EUV reticle 200 in an x-direction. For example, the electron source 110 may include a first electron source 110-1 disposed on the left side of the EUV reticle 200 and a second electron source 110-2 disposed on the right side of the EUV reticle 200 in the x-direction. However, the number of electron sources 110 is not limited to two. For example, in some embodiments, only one electron source 110 may be disposed on one side of the EUV reticle 200 in the x-direction. Additionally, in some embodiments, one or more electron sources 110 may be disposed on each side of the EUV reticle 200 in the x-direction.

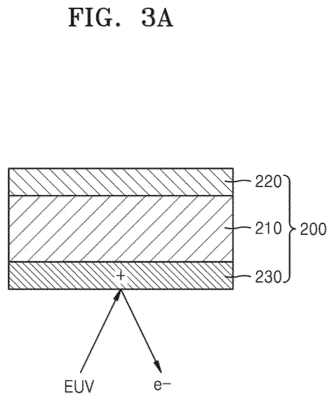

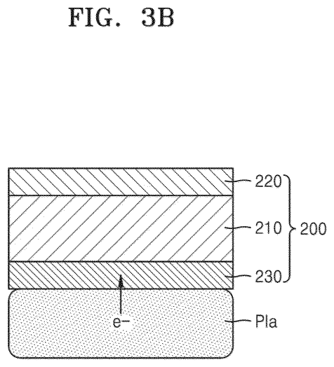

The EUV reticle 200 may include a body layer 210, which is dielectric, and an upper layer 220 and a lower layer 230, which are conductive layers. In some embodiments, the EUV reticle 200 may also be referred to as an EUV mask. The EUV reticle 200 is described in more detail through the description of FIGS. 3A and 3B. In addition, the slit plate 300 may be disposed below the EUV reticle 200, and a slit S may be formed in the slit plate 300. For example, when the x-direction corresponds to a scanning direction in the EUV exposure process, the slit S extends in the y-direction but may have a parabolic shape that is convex in the x-direction.

The plasma sensor 120 may detect plasma in the EUV exposure process. The plasma sensor 120 may be placed in the space between the EUV reticle 200 and the slit plate 300. Additionally, as shown in FIG. 1, the plasma sensor 120 may be disposed adjacent to the slit S of the slit plate 300. The plasma sensor 120 may include a passive electrical sensor or an optical sensor that measures electromagnetic waves emitted by plasma. However, the type of plasma sensor 120 is not limited to the above-described sensors.

In the contamination prevention device 100 for an EUV reticle according to one or more embodiments, the plasma sensor 120 may include a first plasma sensor 120-1 disposed on the left side of the slit S and a second plasma sensor 120-2 disposed on the right side of the slit S in the x-direction. However, the number of plasma sensors 120 is not limited to two. For example, one plasma sensor 120 may be placed, or three or more plasma sensors 120 may be placed. In some embodiments, the plasma sensor 120 may be omitted.

The surface charge sensor 130 may detect a surface charge of the EUV reticle 200. The surface charge sensor 130 may be disposed in the space between the EUV reticle 200 and the slit-plate 300. Additionally, as shown in FIG. 1, the surface charge sensor 130 may be disposed adjacent to the slit S of the slit plate 300. The surface charge sensor 130 may measure the charge charged on the surface of the EUV reticle 200, for example, static electricity. Accordingly, the surface charge sensor 130 may include an electrostatic sensor. However, the type of surface charge sensor 130 is not limited to electrostatic sensors.

In the EUV exposure process, because plasma is concentrated around the slit S of the slit plate 300, the plasma sensor 120 may be placed closer to the slit S than the surface charge sensor 130. For example, the plasma sensor 120 may be disposed immediately adjacent to the slit S in the x-direction, and the surface charge sensor 130 may be disposed between the electron source 110 and the plasma sensor 120 in the x-direction. In addition, in FIG. 1, although the surface charge sensor 130 is disposed adjacent to the plasma sensor 120 in the x-direction, in one or more embodiments, the surface charge sensor 130 may be disposed at an intermediate position between the electron source 110 and the plasma sensor 120 in the x-direction, or adjacent to the electron source 110.

In the contamination prevention device 100 for the EUV reticle according to one or more embodiments, the surface charge sensor 130 may include a first surface charge sensor 130-1 disposed on the left side of the slit S and a second surface charge sensor 130-2 disposed on the right side of the slit S in the x-direction. However, the number of surface charge sensors 130 is not limited to two. For example, one surface charge sensor 130 may be placed, or three or more surface charge sensor 130 may be placed. In some embodiments, the surface charge sensor 130 may be omitted. Additionally, both the plasma sensor 120 and the surface charge sensor 130 may be omitted in some embodiments, and the contamination prevention device 100 for the EUV reticle may include only the electron source 110.

The contamination prevention device 100 for the EUV reticle according to one or more embodiments may include the electron source 110, the plasma sensor 120, and the surface charge sensor 130, and may sense a state without plasma through the plasma sensor 120 and sense the surface charge of the EUV reticle 200 through the surface charge sensor 130. When the surface of the EUV reticle 200 is charged with positive charge, the contamination prevention device 100 for the EUV reticle may neutralize the EUV reticle 200 by emitting electrons into the space between the EUV reticle 200 and the slit-plate 300 through an electron source 110. The contamination prevention device 100 for the EUV reticle according to one or more embodiments may neutralize the EUV reticle 200 in real time in the EUV exposure process through the above-described method. Accordingly, by blocking the electric force between the fine particles and the EUV reticle 200, the fine particles may be prevented from moving to the EUV reticle 200 and sticking to the EUV reticle 200, making it easier to remove particles during subsequent flushing operations. Thus, the contamination prevention device 100 for the EUV reticle may more effectively prevent the EUV reticle 200 from being contaminated by the fine particles. Here, the flushing operation may be an operation of discharging particles to the outside using air currents.

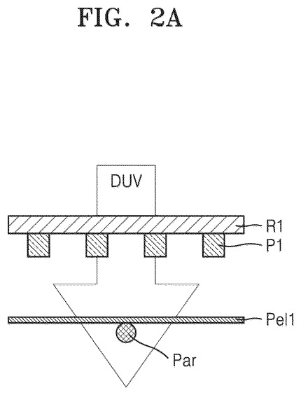

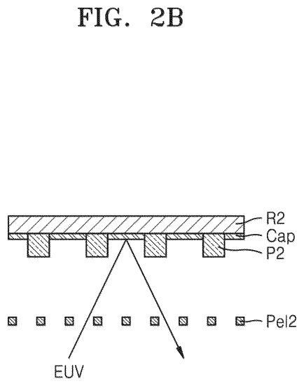

FIGS. 2A and 2B are conceptual diagrams illustrating prevention of contamination of a reticle in a deep ultra-violet (DUV) exposure process and an EUV exposure process.

Referring to FIGS. 2A and 2B, as shown in FIG. 2A, in the case of the DUV exposure process, a transmissive reticle R1 may be used, and accordingly, a pellicle Pell may be disposed at the lower portion of the transmissive reticle R1, and the pellicle Pell may block particles Par from attaching to the transmissive reticle R1. However, as shown in FIG. 2B, for the EUV exposure process, a reflective reticle R2 may be used. When a pellicle Pel2 is placed below the reflective reticle R2, EUV light must pass through the pellicle Pel2 twice, and due to the absorption characteristics of the EUV light, there is a problem that the pellicle Pel2 may be quickly damaged by heat and EUV exposure efficiency may be greatly reduced. Therefore, the pellicle Pel2 is not substantially used in the EUV exposure process.

In FIGS. 2A and 2B, P1 and P2 are patterns on the reticles R1 and R2, and in FIG. 2B, Cap is a capping layer. In addition, the exposure process is a process of transferring the pattern of the reticles R1 and R2 to the wafer using exposure light to form a pattern required for the wafer. Because patterns are generally formed on multiple wafers with one reticle R1 or R2, contamination of the reticle, for example, contamination with fine particles attached to the surface of the reticle R1 or R2, may cause defects in numerous wafers, resulting in a large number of defective products, or worsening productivity by causing a situation where the process must be restarted.

FIGS. 3A and 3B are conceptual diagrams illustrating an operation of an EUV reticle being charged in the EUV exposure process.

Referring to FIG. 3A, in the EUV exposure process, as EUV light EUV is reflected from the EUV reticle 200, electrons are emitted from the lower layer 230 of the EUV reticle 200 due to the photoelectric effect, and the lower layer 230 of the EUV reticle 200 may be charged with positive charges. As described above, the EUV reticle 200 may include a body layer 210, an upper layer 220, and the lower layer 230. The body layer 210 may include a substrate and a reflective multilayer film on the substrate. The substrate may be formed of a low thermal expansion coefficient material (LTEM) such as, for example, quartz. The reflective multilayer film is formed on the substrate and may reflect EUV light. The reflective multilayer film may have, for example, a structure in which molybdenum (Mo) films and silicon (Si) films are alternately stacked in dozens or more layers. However, the materials that make up the reflective multilayer film are not limited to Mo and Si. The body layer 210 may correspond to a dielectric layer.

The lower layer 230 may include a capping layer and an absorption layer. The capping layer may include, for example, ruthenium (Ru). According to one or more embodiments, the capping layer may be omitted. The absorption layer is a layer on which a pattern is formed and may be formed of, for example, tantalum nitride (TaN), tantalum nitrogen oxide (TaNO), tantalum boron oxide (TaBO), nickel (Ni), gold (Au), silver (Ag), carbon (C), telluride (Te), platinum (Pt), palladium (Pd), chromium (Cr), etc. However, the material of the absorption layer is not limited to the above-mentioned materials. The lower layer 230 may be a conductive layer.

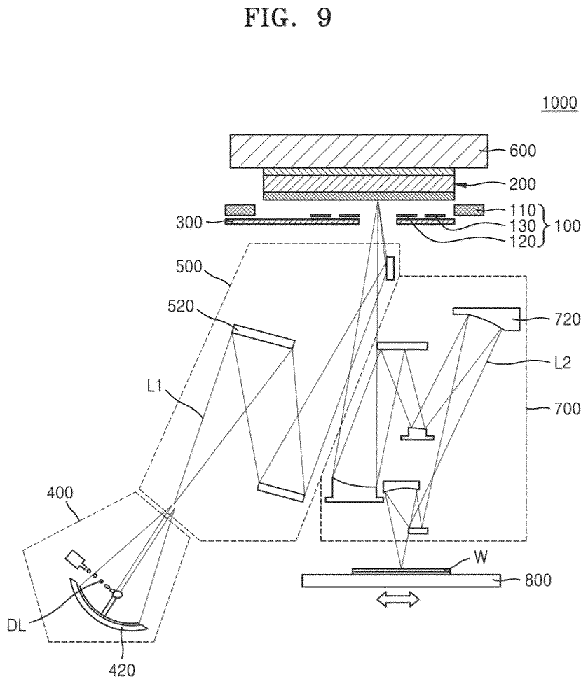

The upper layer 220 may be formed on the body layer 210. The upper layer 220 may be formed to attach the EUV reticle 200 to the reticle stage (see 600 in FIG. 9) through electrostatic force. Accordingly, the upper layer 220 may be a conductive layer. For example, the upper layer 220 may be formed by coating chromium nitride chromium nitride (CrN), a conductive material, on the body layer 210. However, the material of the upper layer 220 is not limited to CrN.

Referring to FIG. 3B, generally, H2 gas is supplied to maintain cleanliness within EUV exposure equipment, and in the EUV exposure process, H2 gas may be ionized by EUV to generate EUV induced plasma Pla. Electrons e-of the EUV induced plasma Pla may reach the EUV reticle 200 and cause neutralization of the EUV reticle 200, but may be significantly lacking compared to (+) charge on the surface of the EUV reticle 200 generated due to repetitive EUV pulses in the EUV exposure process. For reference, as described above, because the surface layer of the EUV reticle 200, for example, the lower layer 230, is a conductive layer, positive charges may more easily move so that the lower surface may exhibit an overall positive voltage. For example, the average voltage due to the charge on the surface of the EUV reticle 200 is at the level of about 1 V to about 2 V. In addition, electrons e-of the EUV induced plasma Pla are used to neutralize the EUV reticle 200, but the electrons e-of the EUV induced plasma Pla also move and attach to nearby particles, thereby charging the particles to a (−) charge state.

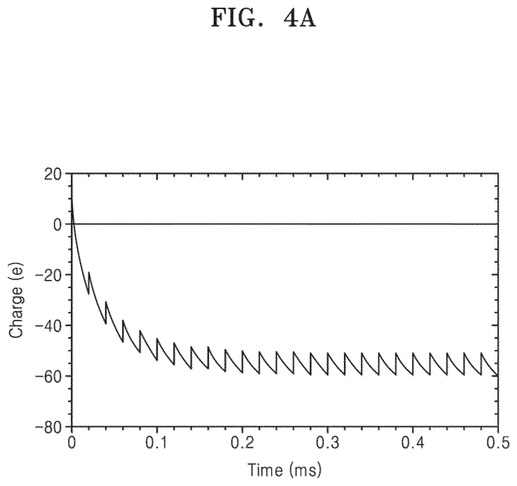

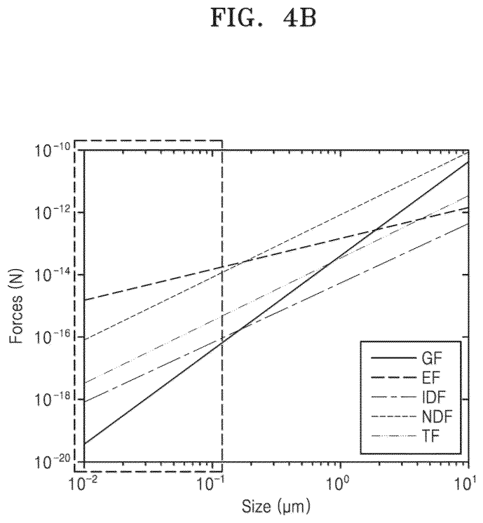

FIGS. 4A and 4B are graphs illustrating a charge amount of particles over time and forces acting on particles depending on size during the exposure process. FIG. 4A shows the charge of particle versus time for a particle with a diameter of 100 nm, and the unit of the y-axis is the electron charge unit. In in electron charge units, 1 may correspond to the charge of one electron. In FIG. 4B, x-axis represents the size of the particle, for example, the diameter of the particle, and GF is gravitation force, EF is electric force, IDF is ion drag force, NDF is neutral drag force, and TF is thermo-phoretic force.

Referring to FIG. 4A, in the case of fine particles with a diameter of 100 nm, the fine particles may be charged more quickly. For example, the particles are saturated to a charge level of almost −60 electrons at about 0.1 ms.

Referring to FIG. 4B, as may be seen with reference with the dotted square, when the particle size is less than or equal to about 0.1 um, that is, less than or equal to about 100 nm, the force that acts the most on the particle during the exposure process is the electric force EF. Additionally, when the size of the particle is less than or equal to 100 nm, the ion drag force IDF or the neutral drag force NDF acts on the particle relatively less than the electric force EF.

As described above, the EUV reticle 200 is charged with positive charges due to the accumulation of photoelectric effects by EUV pulses in the EUV exposure process, and the particles are charged with negative charges by attaching electrons generated from the EUV induced plasma. Accordingly, electrical attraction occurs between the EUV reticle 200 and the particle, and the particle adheres to the surface of the EUV reticle 200. In particular, as may be seen with reference to the graph in FIG. 4A, in the case of fine particles of about 100 nm or less, the (−) charge is more easily charged. In addition, as shown in the graph of FIG. 4B, the electric force acts more strongly than the drag force caused by H2 gas, which may prevent particles from moving toward the reticle, and the less the particle size, the greater the impact of the electric force. Thus, fine particles adhere to the surface of the EUV reticle 200.

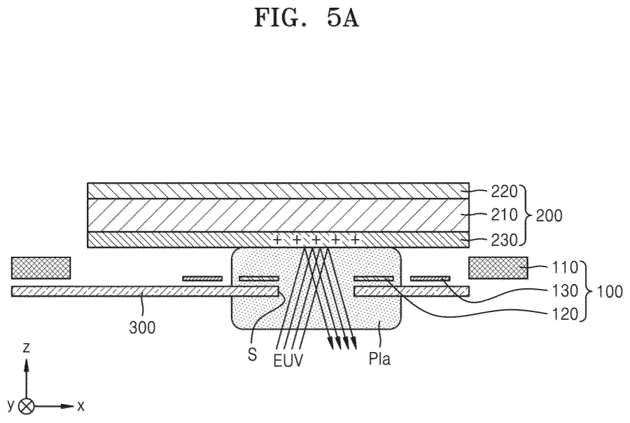

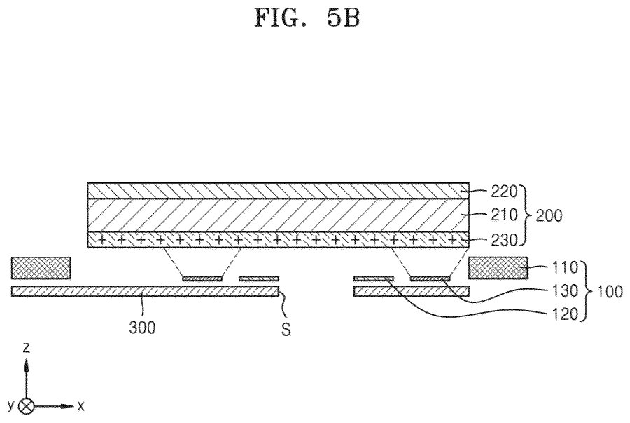

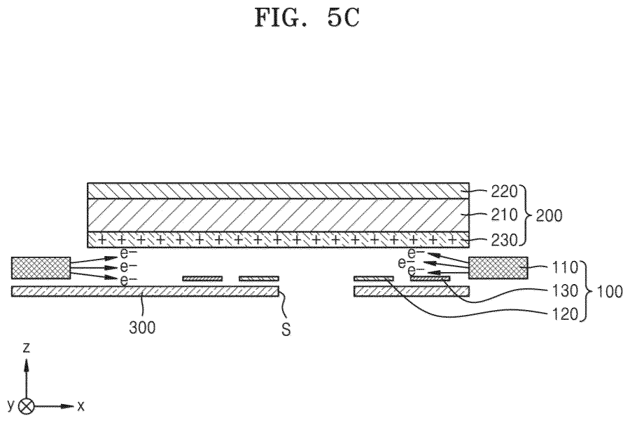

FIGS. 5A to 5C are conceptual diagrams illustrating a process of preventing contamination of the EUV reticle through the contamination prevention device for EUV reticle shown in FIG. 1. The descriptions already given in the description of FIGS. 1 to 4B are briefly given or omitted.

Referring to FIG. 5A, in the EUV exposure process, EUV light EUV may be incident on and reflected from the EUV reticle 200 through the slit S of the slit-plate 300. In this case, H2 gas can be converted into plasma by EUV light to generate EUV-induced plasma Pla. Additionally, the surface of the EUV reticle 200, that is, the lower layer 230, may be charged with positive charges due to the photoelectric effect caused by the EUV pulse. In this embodiment, the contamination prevention device 100 for EUV reticle checks the EUV induced plasma Pla through the plasma sensor 120. The presence of the EUV induced plasma Pla is checked because when the surface charge sensor 130 senses the charge on the surface of the EUV reticle 200, the surface charge sensor 130 may cause an error sensing the charge of the EUV induced plasma Pla rather than the charge on the surface of the EUV reticle 200.

Referring to FIG. 5B, after checking that EUV induced plasma Pla does not exist through the plasma sensor 120, the charge on the surface of the EUV reticle 200 is sensed through the surface charge sensor 130. For example, the surface charge sensor 130 may sense the positive charges of the lower layer 230 of the EUV reticle 200.

Referring to FIG. 5C, when it is confirmed through the surface charge sensor 130 that the surface of the EUV reticle 200, that is, the lower layer 230 of the EUV reticle 200, is charged with positive charges, electrons e-are emitted through the electron source 110. The electrons e-from the electron source 110 may be emitted into the space between the EUV reticle 200 and the slit-plate 300 in the x-direction. Hereinafter, the process of neutralizing the EUV reticle 200 through the emitted electrons e-is described in more detail.

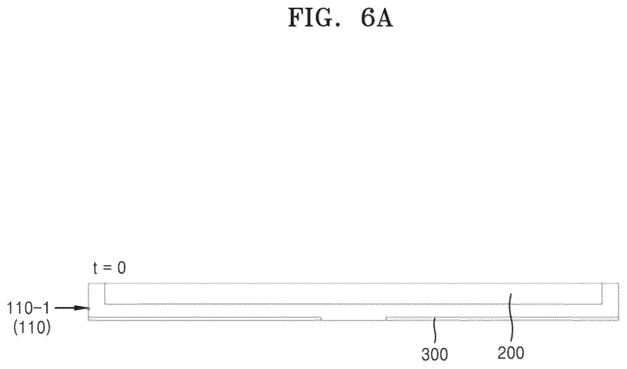

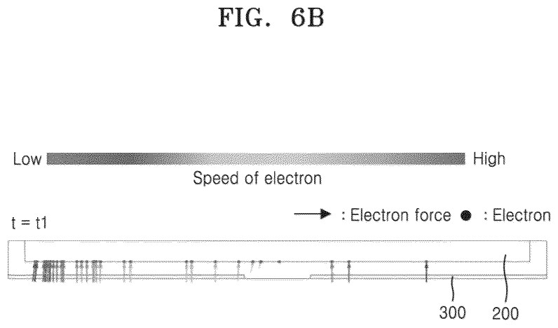

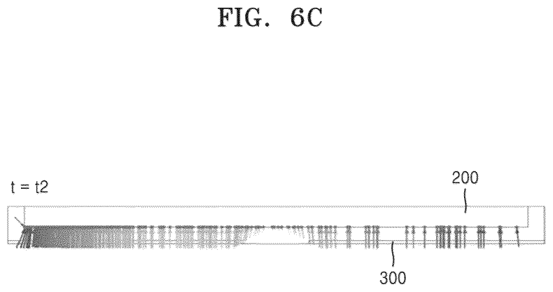

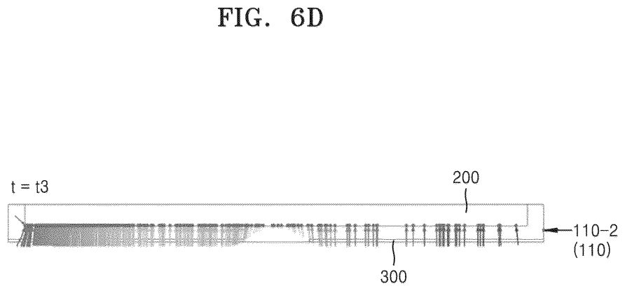

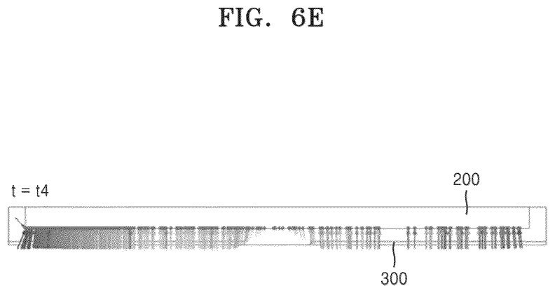

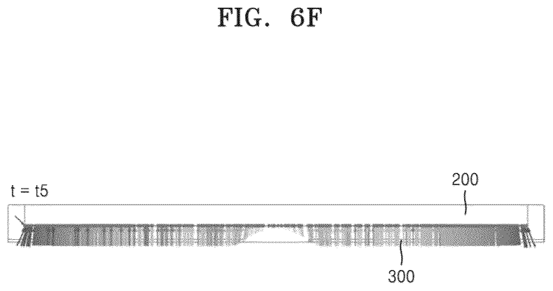

FIGS. 6A to 6F are conceptual diagrams illustrating in more detail a process of neutralizing the EUV reticle through electron emission from an electron source shown in FIG. 5C. In FIGS. 6A to 6F, the direction of the arrow indicates the direction of the electric force, the length of the arrow indicates the strength of the electric force, and the black and white shades of the arrow indicates the speed of the electron. For reference, for convenience, the reference band for the black and white shades is shown only in FIG. 6B, but may be commonly applied to FIGS. 6C to 6F.

Referring to FIG. 6A, first, at t=0, electrons begin to be emitted from the first electron source 110-1 located on the left side in the x-direction.

Referring to FIG. 6B, at t=t1, the electrons emitted from the first electron source 110-1 move to the surface of the EUV reticle 200 by electric force, attach to the surface of the EUV reticle 200, and move to the right side in the x-direction. As described above, the surface of the EUV reticle 200 is the lower layer 230, which is a conductive layer, and therefore the electrons may freely and quickly move on the surface of the EUV reticle 200. For example, t1 may be 0.001 s. Referring to FIG. 6B, relatively few electrons are placed on the right side of the x-direction, so the electrons may move more quickly toward the surface of the EUV reticle 200. For example, on the right side of the x-direction, the moving speed of electrons toward the surface of the EUV reticle 200 may be relatively high.

Referring to FIG. 6C, at t=t2, the electrons continuously emitted from the first electron source 110-1 move to the surface of the EUV reticle 200 by electric force and attach to the surface of the EUV reticle 200, moving to the right in the x-direction. Accordingly, the electrons may be placed on most of the surface of the EUV reticle 200 on the left of the slit in the x-direction. For example, t2 may be 0.025 s. Referring to FIG. 6C, relatively few electrons are still placed on the right side of the x-direction such that the moving speed of the electrons may be relatively high.

Referring to FIG. 6D, at t=t3, emission of electrons from the first electron source 110-1 on the left side in the x-direction is blocked, and electrons begin to be emitted from the second electron source 110-2 on the right side in the x-direction. For example, t2 may be 0.026 s.

Referring to FIG. 6E, at t=t4, electrons emitted from the second electron source 110-2 may move to the surface of the EUV reticle 200 by electric force, attach to the surface of the EUV reticle 200, and move to the left in the x-direction. For example, t1 may be 0.027 s. In addition, referring to FIG. 6E, relatively few electrons are placed adjacent to the curved slit in the center of the x-direction, and the moving speed of electrons at a location adjacent to the curved slit may be relatively high.

Referring to FIG. 6F, at t=t5, the electrons emitted from the second electron source 110-2 move to the surface of the EUV reticle 200 by electric force and attach to the surface of the EUV reticle 200, moving to the left side in the x direction. Accordingly, electrons may also be placed on most of the surface of the EUV reticle 200 on the right of the curved slit in the x direction. For example, t2 may be 0.005 s. As a result, the EUV reticle 200 may be quickly and uniformly neutralized within a short time of about 0.05 s through sequential electron emission from the first electron source 110-1 and the second electron source 110-2.

With reference to FIGS. 6A to 6F, the method of neutralizing the EUV reticle 200 through sequential electron emission using the first and second electron sources 110-1 and 110-2 has been described, but the method of neutralizing the EUV reticle 200 by the contamination prevention device 100 for EUV reticle according to embodiments are not limited thereto. For example, the contamination prevention device 100 for an EUV reticle according to one or more embodiment may neutralize the EUV reticle 200 by simultaneously emitting electrons from the first and second electron sources 110-1 and 110-2, or by emitting electrons from both the first and second electron sources 110-1 and 110-2, but emitting electrons at different emission times from the first 110-1 and the second electron sources 110-2. In the case of including one electron source 110, on the side of the EUV reticle 200, electrons may be emitted into the space between the EUV reticle 200 and the slit-plate 300 until the entire EUV reticle 200 is neutralized. In addition, whether the entire EUV reticle 200 is neutralized may be sensed through the surface charge sensor 130.

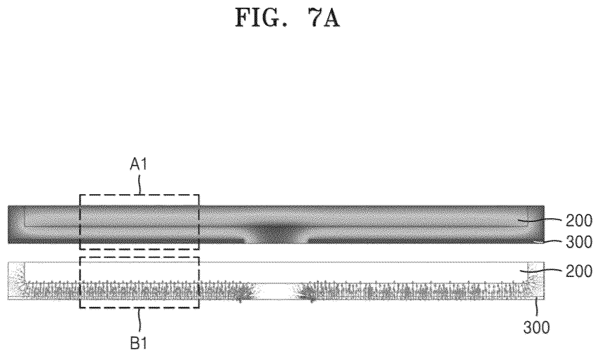

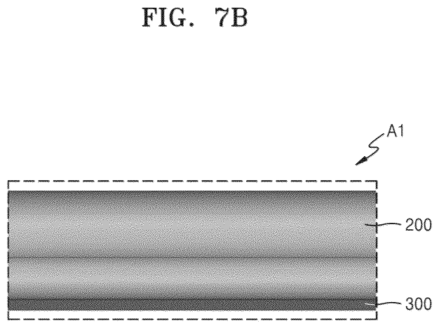

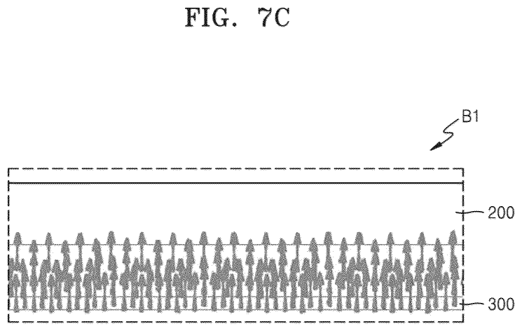

FIGS. 7A to 7C are conceptual diagrams illustrating a speed at which particles move by electric force while the EUV reticle is charged with positive charges. FIG. 7B shows an enlarged view of part A1 of FIG. 7A, and FIG. 7C shows an enlarged view of part B1 of FIG. 7A. With reference to FIG. 1, FIGS. 7A to 7C are described, and the descriptions already given in the description of FIGS. 1 to 6F are briefly given or omitted.

Referring to FIGS. 7A to 7C, FIG. 7B and the upper portion of FIG. 7A show the voltage of the EUV reticle 200 and the slit plate 300 in black and white shades. In FIGS. 7A and 7B, the dark black color on the lower surface of the EUV reticle 200 and the slit portion of the slit plate 300 may correspond to a relatively high voltage area, and the dark black color on the upper surface and both sides of the EUV reticle 200 and the slit plate 300 may correspond to a relatively low voltage area. It may be seen through FIGS. 7A and 7B that the lower surface of the EUV reticle 200 is charged with positive charges and has a relatively high voltage. For example, the lower surface of the EUV reticle 200 may have a voltage of approximately 2 V.

The lower portion of FIG. 7A and FIG. 7C show the speed at which particles move. The particles may move to the lower surface of the EUV reticle 200 by electric force. As described above, the electric force is an electric attraction between the positive charges on the lower surface of the EUV reticle 200 and the negative charges of the particles, and may increase as it approaches the lower surface of the EUV reticle 200. Accordingly, the moving speed of particles may also increase as the particles approach the lower surface of the EUV reticle 200.

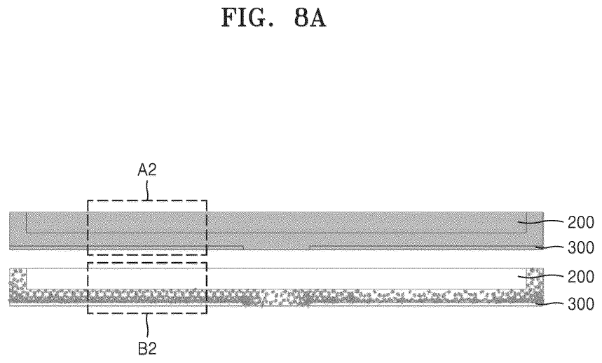

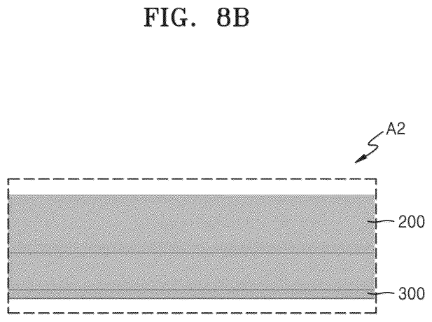

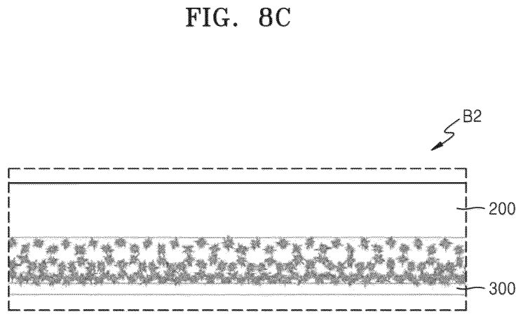

FIGS. 8A to 8C are conceptual diagrams illustrating a direction and speed at which particles move while the EUV reticle is neutralized. FIG. 8B shows an enlarged view of portion A2 of FIG. 8A, and FIG. 8C shows an enlarged view of portion B2 of FIG. 8A. With reference to FIG. 1, FIGS. 8A to 8C are described, and the descriptions already given in the description of FIGS. 1 to 6F are briefly given or omitted.

Referring to FIGS. 8A to 8C, FIG. 8B and the upper portion of FIG. 8A show the voltages of the EUV reticle 200 and the slit-plate 300 in black and white shades. For example, light black may correspond to a voltage of about 0 V. Accordingly, the neutralized EUV reticle 200 may have a voltage of about 0 V as a whole, and the slit-plate 300 may also have a voltage of about 0 V.

FIG. 8C and the lower portion of FIG. 8A and show the speed at which the particles move. Because the particles do not receive electrical force from the EUV reticle 200, the moving speed of the particles is relatively small and the moving direction of the particles may move almost randomly in place. Therefore, the particles may be more easily removed through a subsequent flushing operation.

FIG. 9 is a conceptual diagram schematically illustrating an EUV exposure apparatus including a device for preventing contamination of an EUV reticle according to one or more embodiments. With reference to FIG. 1, FIG. 9 is described, and the descriptions already given in the description of FIGS. 1 to 8C are briefly given or omitted.

Referring to FIG. 9, an EUV exposure apparatus 1000 (EUV exposure apparatus) including a contamination prevention device for EUV reticle according to the one or more embodiments may include a contamination prevention device 100 for EUV reticle, a slit plate 300, an EUV source 400, a first optical system 500, a reticle stage 600, a second optical system 700, and a wafer stage 800.

The contamination prevention device 100 for EUV reticle may include an electron source 110, a plasma sensor 120, and a surface charge sensor 130. The contamination prevention device 100 for EUV reticle may be the contamination prevention device 100 for EUV reticle shown in FIG. 1. Accordingly, detailed description of the contamination prevention device 100 for EUV reticle is omitted.

The EUV source 400 may generate and output EUV light L1 with a relatively high energy density within a wavelength range of about 5 nm to about 50 nm. For example, the EUV source 400 can generate and output EUV light L1 with a wavelength of 13.5 nm and a relatively high energy density. The EUV source 400 may be a plasma-based source or a synchrotron radiation source. Here, the plasma-based source refers to a source that generates plasma and uses the light emitted by the plasma and may include a laser-produced plasma (LPP) source, a discharge-produced plasma (DPP) source, etc. In the case of an LLP source, EUV light may be generated from tin plasma generated by focusing a high-power CO2 laser on a tin droplet DL.

In the EUV exposure apparatus 1000 according to the one or more embodiments, the EUV source 400 may be, for example, a plasma-based source. In the EUV exposure apparatus 1000 according to the one or more embodiments, the EUV source 400 is not limited to a plasma-based source. In addition, in the case of plasma-based sources, in order to increase the energy density of the illumination light incident on the first optical system 500, a condensing mirror 420, such as an elliptical mirror and/or a spherical mirror that focuses EUV light may be included. The condensing mirror 420 may also be referred to as an EUV collector.

The first optical system 500 may include a plurality of mirrors 520. For example, in the EUV exposure apparatus 1000 according to the one or more embodiments, the first optical system 500 may include two or three mirrors 520. However, the number of mirrors in the first optical system 500 is not limited to two or three. The first optical system 500 may transmit the EUV light L1 generated by the EUV source 400 to an EUV reticle 200. For example, the EUV light L1 generated by the EUV source 400 may be incident on the EUV reticle 200 disposed on the reticle stage 600 through reflection by the mirrors 520 in the first optical system 500. The EUV light L1 may be incident on an EUV reticle 200 through the slit S of the slit plate 300. The EUV light L1 may be incident on the EUV reticle 200 in the shape of a curved slit. The curved slit shape of EUV light L1 may have a parabolic two-dimensional curved shape on an x-y plane.

As described above, the EUV reticle 200 may be a reflective reticle and may include a reflective multilayer film for reflecting EUV on a substrate formed of LTEM such as quartz and an absorption layer pattern formed on the reflective multilayer film. The reflective multilayer film may have, for example, a structure in which molybdenum films and silicon films are alternately stacked in dozens or more layers. The absorption layer may be formed of, for example, TaN, TaNO, TaBO, Ni, Au, Ag, C, Te, Pt, Pd, Cr, etc. However, the material of the reflective multilayer film and the material of the absorption layer are not limited to the above-mentioned materials. A capping layer of ruthenium (Ru) may be disposed on the upper surface of the reflective multilayer film, and an absorption layer may be disposed on the capping layer. Depending on the embodiment, the capping layer may be omitted.

The EUV reticle 200 reflects the EUV light L1 incident through the first optical system 500 and makes the reflected EUV light L1 incident on the second optical system 700. The EUV reticle 200 reflects the EUV light L1 incident from the first optical system 500. For example, the EUV reticle 200 structures the EUV light L1 depending on a pattern composed of an absorption layer on a reflective multilayer film and makes the structured EUV light incident to the second optical system 700. The structured EUV light L2 may be incident on the second optical system 700 while retaining information in the form of a pattern on the EUV reticle 200. Additionally, the structured EUV light L2 may be transmitted through the second optical system 700 and projected onto an EUV exposure target. Accordingly, an image corresponding to the pattern shape on the EUV reticle 200 may be transferred to the EUV exposure target. Here, the EUV exposure target may be a substrate including a semiconductor material, such as silicon, for example, a wafer W. Hereinafter, unless otherwise specified, the EUV exposure target is used in the same concept as the wafer W.

The second optical system 700 may include a plurality of mirrors 720. In the EUV exposure apparatus 1000 according to the one or more embodiments, the second optical system 700 may include 4 to 8 mirrors 720. However, the number of mirrors 720 of the second optical system 700 is not limited to 4 to 8. The second optical system 700 may transmit the EUV light L2 reflected from the EUV reticle 200 to the wafer W through reflection of the mirrors 720.

The EUV reticle 200 may be placed on the reticle stage 600. The reticle stage 600 may move in the x and y directions on the x-y plane and in the z-direction perpendicular to the x-y plane. Additionally, the reticle stage 600 may rotate about the z-axis, the x-axis, or the y-axis. By moving and rotating the reticle stage 600, the EUV reticle 200 may move in the x-direction, y-direction, or z-direction, and may also rotate about the x-axis, y-axis, or z-axis.

In addition, the reticle stage 600 may fix the EUV reticle 200 by electrostatic force or vacuum adsorption. Accordingly, the reticle stage 600 may include components corresponding to an electrostatic chuck or a vacuum chuck. In the EUV exposure apparatus of the embodiment, the reticle stage 600 may include an electrostatic chuck. Accordingly, the EUV reticle 200 may include an upper layer 220 of a conductive layer.

The wafer W that is subject to EUV exposure may be placed on the wafer stage 800. The wafer stage 800 may move in the x and y directions on the x-y plane and in the z-direction perpendicular to the x-y plane. Additionally, the wafer stage 800 may rotate about the z-axis, the x-axis, or the y-axis. By moving and rotating the wafer stage 800, the wafer W may move in the x-direction, y-direction, or z-direction, and may also rotate about the x-axis, y-axis, or z-axis.

The EUV exposure apparatus 1000 according to the one or more embodiments may include the contamination prevention device 100 for EUV reticle disposed on the side and lower portion of the EUV reticle 200. In detail, the contamination prevention device 100 for EUV reticle may include an electron source 110, a plasma sensor 120, and a surface charge sensor 130. The electron source 110 may be placed adjacent to a side of EUV reticle 200 outside the space between EUV reticle 200 and slit-plate 300. The plasma sensor 120 and the surface charge sensor 130 may be disposed inside the space between the EUV reticle 200 and the slit plate 300. The contamination prevention device 100 for EUV reticle may sense the absence of plasma and the surface charge of the EUV reticle 200 through the plasma sensor 120 and the surface charge sensor 130. When the surface of the EUV reticle 200 is charged with positive charges, the contamination prevention device 100 for EUV reticle may neutralize the EUV reticle 200 by emitting electrons through the electron source 110 into the space between the EUV reticle 200 and the slit-plate 300. Accordingly, the contamination prevention device 100 for EUV reticle may more effectively prevent contamination of the EUV reticle 200 from fine particles by preventing fine particles from attaching to the EUV reticle 200 by electric force and allowing fine particles to be more easily removed through subsequent flushing operations. As a result, the EUV exposure apparatus 1000 according to the one or more embodiments includes the contamination prevention device 100 for EUV reticle to prevent contamination of the EUV reticle 200, thereby greatly improving the productivity and reliability of the EUV exposure process.

While embodiments have been described with reference to the figures, it will be understood by those of ordinary skill in the art that various changes in form and details may be made therein without departing from the spirit and scope as defined by the following claims and their equivalents.

What is claimed is:

1. A contamination prevention device for extreme ultra-violet (EUV) reticle, comprising:
at least one electron source comprising a first electron source on a first side of the EUV reticle outside a space between the EUV reticle and a slit-plate,
wherein, during an EUV exposure process, the at least one electron source is configured to emit the electrons into the space to neutralize the EUV reticle.

2. The contamination prevention device of claim 1, wherein, when a scan direction is a first direction in the EUV exposure process, the at least one electron source comprises a second electron source on a second side of the EUV reticle in the first direction with respect to the first electron source.

3. The contamination prevention device of claim 2, further comprising a first sensor in the space adjacent to a slit position of the slit-plate, the first sensor being configured to detect plasma during the EUV exposure process.

4. The contamination prevention device of claim 3, wherein the first sensor comprises a passive electrical sensor or optical sensor, and
wherein the first sensor is configured to measure electromagnetic waves emitted by plasma.

5. The contamination prevention device of claim 3, further comprising a second sensor in the space adjacent to the slit position of the slit-plate, the second sensor being configured to measure a surface charge of the EUV reticle.

6. The contamination prevention device of claim 1, wherein, when a scan direction is a first direction during the EUV exposure process, the at least one electron source comprises a second electron source on the second side of the EUV reticle in the first direction, and
wherein the contamination prevention device further comprises:
a first sensor in the space adjacent to a slit position of the slit-plate, the first sensor being configured to detect plasma during the EUV exposure process; and
a second sensor in the space adjacent to the slit position of the slit-plate, the second sensor being configured to measure a surface charge of the EUV reticle during the EUV exposure process.

7. The contamination prevention device of claim 6, wherein the first electron source and the second electron source are configured to emit the electrons based on detecting a state in which there is no plasma by the first sensor and detecting a state in which a surface of the EUV reticle is charged with positive charges by the second sensor.

8. The contamination prevention device for EUV reticle of claim 7, wherein the first electron source and the second electron source are configured to emit the electrons by one of a first method, a second method, and a third method,
wherein, in the first method, the electrons are sequentially emitted by the first electron source on the first side of the EUV reticle, then electron emission is blocked from the first electron source on the first side, and the electrons are simultaneously emitted from the second electron source on the second side of the of the EUV reticle,
wherein, in the second method, the electrons are simultaneously emitted from the first electron source and the second electron source on the first side and the second side of the EUV reticle, and
wherein, in the third method, the electrons are emitted from the first electron source and the second electron source on the first side and the second side of the EUV reticle, and time points at which the electrons are emitted from the first electron source and the second electron source are different from each other.

9. The contamination prevention device of claim 1, wherein, when a scan direction is a first direction during the EUV exposure process, the at least one electron source is configured to emit the electrons into the space in the first direction.

10. The contamination prevention device of claim 1, wherein the at least one electron source comprises an electron gun.

11. A contamination prevention device for extreme ultra-violet (EUV) reticle, comprising:
at least one electron source comprising a first electron source on a first side of the EUV reticle outside a space between the EUV reticle and a slit-plate;
a first sensor in the space adjacent to a slit position of the slit-plate, the first sensor being configured to detect plasma in an EUV exposure process; and
a second sensor in the space adjacent to the slit position of the slit-plate, the second sensor being configured to measure a surface charge of the EUV reticle,
wherein, during the EUV exposure process, the first electron source is configured to emit the electrons into the space to neutralize the EUV reticle.

12. The contamination prevention device of claim 11, wherein, when a scan direction is a first direction during the EUV exposure process, the at least one electron source comprises a second electron source on a second side of the EUV reticle in the first direction with respect to the first electron source, and
wherein the first electron source and the second electron source are further configured to emit the electrons into the space in the first direction.

13. The contamination prevention device of claim 11, wherein the at least one electron source is further configured to emit the electrons based on detecting a state in which there is no plasma by the first sensor and detecting a state in which a surface of the EUV reticle is charged with positive charges by the second sensor.

14. The contamination prevention device of claim 11, wherein, when a scan direction is a first direction during the EUV exposure process, the at least one electron source comprises a second electron source on a second side of the EUV reticle in the first direction with respect to the first electron source,
wherein the first electron source and the second electron source are further configured to emit the electrons by one of a first method, a second method, and a third method,
wherein, in the first method, the electrons are sequentially emitted by the first electron source on the first side of the EUV reticle, then electron emission is blocked from the first electron source on the first side, and the electrons are simultaneously emitted from the second electron source on the second side of the EUV reticle,
wherein, in the second method, the electrons are simultaneously emitted from the first electron source and the second electron source on the first side and the second side of the EUV reticle, and
wherein, in the third method, the electrons are emitted from the first electron source and the second electron source on the first side and the second side of the EUV reticle, and time points at which the electrons are emitted from the first electron source and the second electron source are different from each other.

15. An extreme ultra-violet (EUV) exposure apparatus comprising:
an EUV source configured to generate and emit EUV;
a reticle stage configured to support an EUV reticle;
a substrate stage configured to support a substrate subject to EUV exposure;
a first optical system configured to transmit EUV from the EUV source to the EUV reticle;
a second optical system configured to transmit EUV reflected from the EUV reticle to the substrate; and
a contamination prevention device configured to prevent contamination of the EUV reticle from particles;
wherein the contamination prevention device for the EUV reticle comprises:
at least one electron source comprising a first electron source on a first side of the EUV reticle external to a space between the EUV reticle and a slit-plate,
wherein, during an EUV exposure process, the at least one electron source is configured to emit the electrons into the space to neutralize the EUV reticle.

16. The EUV exposure apparatus of claim 15, wherein, when a scan direction is a first direction during the EUV exposure process, the at least one electron source comprises a second electron source on a second side of the EUV reticle in the first direction with respect to the first electron source.

17. The EUV exposure apparatus of claim 16, further comprising:
at least one first sensor in the space adjacent to a slit position of the slit-plate, the at least one first sensor being configured to detect plasma during the EUV exposure process; and
at least one second sensor in the space adjacent to the slit position of the slit-plate, the at least one second sensor being configured to measure a surface charge of the EUV reticle during the EUV exposure process.

18. The EUV exposure apparatus of claim 17, wherein the at least one first sensor comprises a passive electrical sensor or optical sensor, the at least one first sensor being configured to measure electromagnetic waves emitted by plasma, and the at least one electron source comprises an electron gun.

19. The EUV exposure apparatus of claim 17, wherein the first electron source and the second electron source are further configured to emit the electrons based on detecting a state in which there is no plasma by the at least one first sensor and detecting a state in which a surface of the EUV reticle is charged with positive charges by the at least one second sensor.

20. The EUV exposure apparatus of claim 19, wherein the first electron source and the second electron source are further configured to emit the electrons by one of a first method, a second method, and a third method,
wherein, in the first method, the electrons are sequentially emitted by the first electron source on the first side of the EUV reticle, then electron emission is blocked from the first electron source on the first side, and the electrons are simultaneously emitted from the second electron source on the second side of the EUV reticle,
wherein, in the second method, the electrons are simultaneously emitted from the first electron source and the second electron source on the first side and the second side of the EUV reticle, and
wherein, in the third method, the electrons are emitted from the first electron source and the second electron source on the first side and the second side of the EUV reticle, and time points at which the first electron source and the second electron source are different from each other.
